(19) United States
(12) Patent Application Publication
(10) Pub. No.: US 2024/0120889 A1
(43) Pub. Date: Apr. 11, 2024

(54) HIGH-FREQUENCY AMPLIFICATION APPARATUS AND MAGNETIC RESONANCE IMAGING APPARATUS

(71) Applicant: CANON MEDICAL SYSTEMS CORPORATION, Otawara-shi (JP)

(72) Inventors: Hirofumi YAMAKI, Nasushiobara (JP); Mitsuyuki MURAKAMI, Nasushiobara (JP); Kosuke HAYASHI, Nasushiobara (JP); Aoi SAKAMITSU, Utsunomiya (JP)

(73) Assignee: CANON MEDICAL SYSTEMS CORPORATION, Otawara-shi (JP)

(21) Appl. No.: 18/480,733

(22) Filed: Oct. 4, 2023

(30) Foreign Application Priority Data
Oct. 5, 2022 (JP) 2022-161161

(51) Int. Cl. H03F 1/56; G01R 33/36; H03F 3/195

(52) U.S. Cl. CPC H03F 1/565; G01R 33/3628; H03F 3/195; H03F 2200/222; H03F 2200/387; H03F 2200/451

(57) ABSTRACT

A high-frequency amplifier apparatus according to an embodiment amplifies high-frequency signals; and includes a balun, amplification circuitry, and matching circuitry. The balun transforms unbalanced signals, which are input, into balanced signals. The amplification circuitry amplifies the balanced signals output from the balun. The matching circuitry is disposed in between the balun and the amplification circuitry, and performs impedance matching. The balun includes an auxiliary winding that is connected to a port of the balun.

### CROSS-REFERENCE TO RELATED APPLICATIONS

This application is based upon and claims the benefit of priority from Japanese Patent Application No. 2022-161161, filed on Oct. 5, 2022, the entire contents of which are incorporated herein by reference.

### FIELD

Embodiments described herein relate generally to a high-frequency amplification apparatus and a magnetic resonance imaging apparatus.

### BACKGROUND

Conventionally, a magnetic resonance imaging apparatus includes a high-frequency amplification apparatus that is meant for the amplification of high frequencies. A high-frequency amplification apparatus includes: a balun that performs transformation between balanced transmission and unbalanced transmission and that performs impedance conversion; and includes a matching circuit that performs impedance matching in accordance with an amplification circuit.

Generally, the size of a balun differs according to the intensity of the magnetostatic field (for example, 1.5 tesla or 3.0 tesla) of a magnetic resonance imaging apparatus. On the other hand, from the perspective of achieving manufacturing efficiency, there have been attempts to standardize the size of the baluns regardless of the intensity of the magnetostatic field of the magnetic resonance imaging apparatuses. In order to standardize the size of the baluns, impedance adjustment is done by adding a coil or an inductance to a balun in a high-frequency amplification apparatus.

However, adding a coil or an inductance results in an increase in the component count, thereby leading to an increase in the component cost.

### BRIEF DESCRIPTION OF THE DRAWINGS

FIG. 1 is a diagram illustrating an example of a magnetic resonance imaging (MRI) apparatus according to a first embodiment;

FIG. 2 is a diagram illustrating an exemplary circuit configuration of a high-frequency amplification apparatus according to the first embodiment;

FIG. 3 is a diagram illustrating examples of planar baluns corresponding to different intensities of the magnetostatic field;

FIG. 4 is a diagram illustrating examples of planar baluns in which a coil and a capacitor are added;

FIG. 5 is a perspective view illustrating an example of a planar balun according to the present embodiment;

FIG. 6 is a front view of an example of a first-layer balun according to the present embodiment; and

FIG. 7 is a diagram illustrating an exemplary circuit configuration of a high-frequency amplification apparatus according to a first modification example.

### DETAILED DESCRIPTION

A high-frequency amplifier apparatus according to an embodiment amplifies high-frequency signals; and includes a balun, amplification circuitry, and matching circuitry. The balun transforms unbalanced signals, which are input, into balanced signals. The amplification circuitry amplifies the balanced signals output from the balun. The matching circuitry is disposed in between the balun and the amplification circuitry, and performs impedance matching. The balun includes an auxiliary winding that is connected to a port of the balun.

Exemplary embodiments of a high-frequency amplification apparatus and a magnetic resonance imaging apparatus are described below with reference to the accompanying drawings. In the embodiments described below, the constituent elements having the same reference numerals assigned thereto are assumed to perform identical operations, and the same explanation is not given in a repeated manner.

### First Embodiment

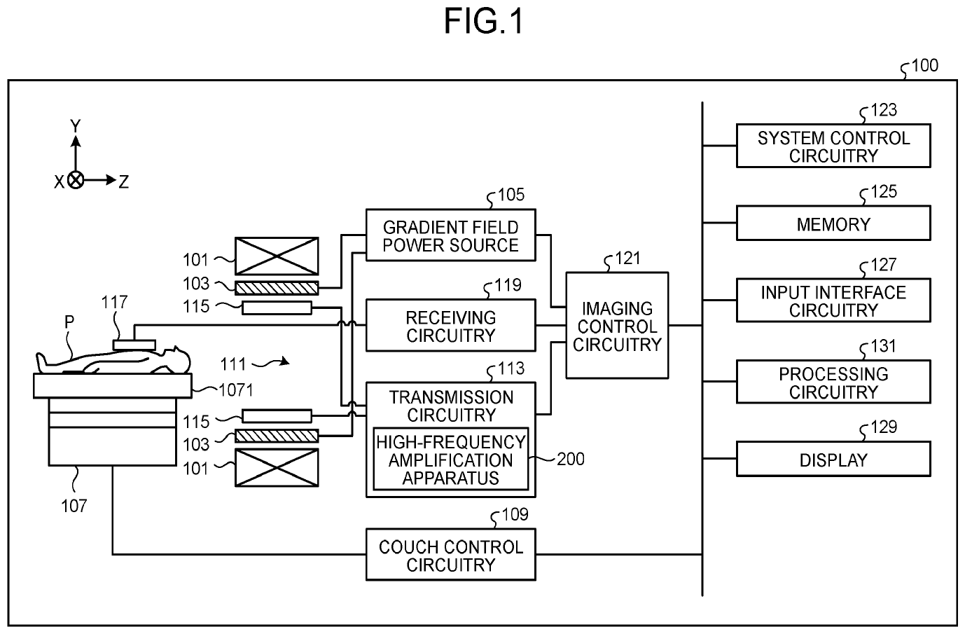

FIG. 1 is a diagram illustrating an example of a magnetic resonance imaging (MRI) apparatus 100 according to a first embodiment. As illustrated in FIG. 1, the MRI apparatus 100 includes a magnetostatic magnet 101, a gradient coil 103, a gradient field power source 105, a couch 107, couch control circuitry 109, transmission circuitry 113, a transmission coil 115, a receiving coil 117, receiving circuitry 119, imaging control circuitry 121, system control circuitry 123, a memory 125, input interface circuitry 127, a display 129, and processing circuitry 131. The MRI apparatus 100 represents an example of a magnetic resonance imaging apparatus.

The magnetostatic magnet 101 is a hollow magnet formed in a substantially cylindrical shape, and generates a substantially uniform magnetostatic field in its internal space. As the magnetostatic magnet 101, for example, a superconducting magnet can be used.

The gradient coil 103 is a hollow coil formed in a substantially cylindrical shape, and is disposed on the inner face of a cylindrical cooling container. The gradient coil 103 individually receives the supply of an electric current from the gradient field power source 105 and generates gradient fields in which the magnetic field intensity changes along the X, Y, and Z axes that are mutually orthogonal. The gradient fields generated along the X, Y, and Z axes are, for example, a slice selection gradient field, a phase encoding gradient field, and a frequency encoding gradient field, respectively. The slice selection gradient field is used in arbitrarily deciding the imaging cross-section. The phase encoding gradient field is used in varying the phase of a magnetic resonance signal (hereinafter, called an MR signal) according to the spatial position. The frequency encoding gradient field is used in varying the frequency of an MR signal according to the spatial position.

The gradient field power source 105 is a power-supply apparatus that, under the control performed by the imaging control circuitry 121, supplies an electric current to the gradient coil 103.

The couch 107 includes a couchtop 1071 on which a subject P is asked to lie down. Under the control performed by the couch control circuitry 109, the couch 107 inserts the couchtop 1071, on which the subject P is lying down, inside a bore 111.

The couch control circuitry 109 controls the couch 107. According to an instruction issued by an operator via the input interface circuitry 127, the couch control circuitry 109 drives the couch 107 and moves the couchtop 1071 in the longitudinal direction and the vertical direction as well as in the horizontal direction in some situations.

The transmission circuitry 113 supplies, to the transmission coil 115 under the control performed by the imaging control circuitry 121, a high-frequency pulse modulated by the Larmor frequency. The transmission circuitry 113 includes, for example, an oscillating unit, a phase selecting unit, a frequency converting unit, an amplitude modulating unit, and a radio frequency (RF) amplifier. The oscillating unit generates an RF pulse having the resonance frequency specific to the target atomic nuclei in the magnetostatic field. The phase selecting unit selects the phase of the RF pulse generated by the oscillating unit. The frequency converting unit performs frequency conversion of the RF pulse output from the phase selecting unit. The amplitude modulating unit modulates the amplitude of the RF pulse, which is output from the frequency converting unit, according to, for example, the sinc function. The RF amplifier amplifies the RF pulse, which is output from the amplitude modulating unit, and supplies it to the transmission coil 115. Meanwhile, the transmission circuitry 113 includes one or more high-frequency amplification apparatuses 200. Each high-frequency amplification apparatus 200 is, for example, an RF amplifier.

The transmission coil 115 is an RF coil placed on the inside of the gradient coil 103. According to the output from the transmission circuitry 113, the transmission coil 115 generates an RF pulse that is equivalent to a high-frequency magnetic field.

The receiving coil 117 is an RF coil that is placed on the inside of the gradient coil 103. The receiving coil 117 receives an MR signal that is radiated from the subject P due to the high-frequency magnetic field. The receiving coil 117 outputs the received MR signal to the receiving circuitry 119. The receiving coil 117 is, for example, a coil array including one or more elements, typically including a plurality of coil elements (hereinafter, called a plurality of coils). In the following explanation, in order to make the explanation more specific, the receiving coil 117 is assumed to be a coil array that includes a plurality of coils.

Meanwhile, in FIG. 1, the transmission coil 115 and the receiving coil 117 are illustrated as separate RF coils. However, alternatively, the transmission coil 115 and the receiving coil 117 can be implemented as an integrated transceiving coil, which corresponds to the target body part for imaging of the subject P. For example, the transceiving coil is a local transceiving RF coil such as a head-region coil.

Under the control performed by the imaging control circuitry 121, the receiving circuitry 119 generates a digital MR signal (hereinafter, MR data) based on the MR signal output from the receiving coil 117. More particularly, the receiving circuitry 119 performs signal processing such as detection and filtering with respect to the MR signal output from the receiving coil 117; performs analog to digital (A/D) conversion (hereinafter called A/D conversion) with respect to the post-signal-processing data; and generates MR data. Then, the receiving circuitry 119 outputs the generated MR data to the imaging control circuitry 121. For example, the MR data is generated in each of a plurality of coils, and is output along with an identification tag of the corresponding coil to the imaging control circuitry 121.

The imaging control circuitry 121 controls the gradient field power source 105, the transmission circuitry 113, and the receiving circuitry 119 according to an imaging protocol output from the processing circuitry 131; and performs imaging of the subject P. The imaging protocol includes the pulse sequence corresponding to the type of examination. In the imaging protocol, the following information is defined: the magnitude of the electric current supplied from the gradient field power source 105 to the gradient coil 103; the timing of supply of the electric current from the gradient field power source 105 to the gradient coil 103; the magnitude and the duration of the high-frequency pulse supplied from the transmission circuitry 113 to the transmission coil 115; the timing of supply of the high-frequency pulse from the transmission circuitry 113 to the transmission coil 115; and the timing of reception of the MR signal by the receiving coil 117. As a result of driving the gradient field power source 105, the transmission circuitry 113, and the receiving circuitry 119 and performing imaging of the subject P; when the MR data is received from the receiving circuitry 119, the imaging control circuitry 121 transfers the received MR data to the processing circuitry 131.

The imaging control circuitry 121 can implement an arbitrary imaging method to collect the MR data related to the generation of an image indicating the distribution of the sensitivity of the receiving coil 117 that is used in the imaging of the subject P. An image indicating the sensitivity of a coil is expressed using data of complex numbers. Regarding the collection of the MR data related to the generation of an image indicating the distribution of the sensitivity of the receiving coil 117; for example, prior to the scanning of the subject P, the imaging control circuitry 121 collects the MR data during the pre-scanning that includes locator scanning. Meanwhile, the imaging control circuitry 121 is implemented using a processor, for example.

The term “processor” implies a circuit such as a central processing unit (CPU), a graphics processing unit (GPU), an application specific integrated circuit (ASIC), or a programmable logic apparatus (for example, a simple programmable logic apparatus (SPLD), a complex programmable logic apparatus (CPLD), or a field programmable gate array (FPGA)).

The system control circuitry 123 includes, as hardware resources, a processor (not illustrated) and a memory (not illustrated) such as a read only memory (ROM) or a random access memory (RAM); and controls the MRI apparatus 100 according to a system control function. More particularly, the system control circuitry 123 reads a system control program stored in the memory, loads it in the memory, and controls the circuitries in the MRI apparatus 100 according to the system control program.

For example, based on the imaging conditions input by the user operator via the input interface circuitry 127, the system control circuitry 123 reads an imaging protocol from the memory 125. Then, the system control circuitry 123 sends the imaging protocol to the imaging control circuitry 121, and controls the imaging of the subject P. The system control circuitry 123 is implemented using, for example, a processor. Alternatively, the system control circuitry 123 can be embedded in the processing circuitry 131. In that case, the system control function is implemented by the processing circuitry 131. Thus, the processing circuitry 131 functions as a substitute for the system control circuitry 123. The processor that implements the system control circuitry 123 is identical to the explanation given above. Hence, that explanation is not given again.

The memory 125 is used to store the following: various programs related to the system control function that is implemented in the system control circuitry 123; various imaging protocols; and imaging conditions including a plurality of imaging parameters that define the imaging protocols. Moreover, the memory 125 is used to store, as computer-executable programs, various functions that are implemented in the processing circuitry 131.

Furthermore, the memory 125 can also be used to store a variety of data received via a communication interface (not illustrated). For example, the memory 125 is used to store the information related to the examination order of the subject P (such as the target body part for imaging and the examination purpose) as received from an information processing system such as a radiology information system (RIS) installed in a healthcare facility.

The memory 125 is implemented using, for example, a semiconductor memory apparatus such as a ROM, a RAM, or a flash memory; or using a hard disk drive (HDD); or using a solid state drive (SSD); or using an optical disk. Alternatively, the memory 125 can be implemented using a CD-ROM drive (CD-ROM stands for Compact Disc Read Only Memory), or a DVD drive (DVD stands for Digital Versatile Disc), or a driving apparatus that performs reading and writing of information with respect to a portable memory medium such as a flash memory.

The input interface circuitry 127 receives input of various instructions (for example, a power activation instruction) and information from the operator. The input interface circuitry 127 is implemented using, for example, a trackball, switch buttons, a mouse, a keyboard, a touchpad enabling the input by touching on the operation screen, a touchscreen configured by integrating a display screen and a touchpad, contactless input circuitry in which an optical sensor is used, or sound input circuitry. The input interface circuitry 127 is connected to the processing circuitry 131; and converts an input operation, which is received from the operator, into an electric signal and outputs the electrical signal to the processing circuitry 131. Meanwhile, in the present written description, the input interface circuitry 127 is not limited to include a physical operation component such as a mouse or a keyboard. Alternatively, for example, an electrical signal processing circuit that receives an electrical signal, which corresponds to an input operation, from an external input apparatus installed separately from the MRI apparatus 100; and that outputs the electrical signal to the control circuitry can also be treated as an example of the input interface circuitry 127.

With respect to a pre-scanning image displayed in the display 129, the input interface circuitry 127 inputs the field of vision (FOV) according to a user instruction. More particularly, according to a range specification instruction issued by the user, the input interface circuitry 127 inputs the field of vision in a locator image displayed in the display 129. Moreover, according to a user instruction that is issued based on the examination order, the input interface circuitry 127 inputs various imaging parameters related to scanning.

The display 129 is used to display various graphical user interfaces (GUIs) and MR images, which are generated by the processing circuitry 131, under the control performed by the processing circuitry 131 or the system control circuitry 123. Moreover, the display 129 is used to display the imaging parameters related to scanning and a variety of information related to image processing. The display 129 is implemented using a display apparatus such as a cathode ray tube (CRT) display, a liquid crystal display (LCD), an organic electroluminescence (EL) display, a light emitting diode (LED) display, a plasma display, or any other display or monitor known in the concerned field.

The processing circuitry 131 is implemented using, for example, the processor explained earlier. The processing circuitry 131 is equipped with various functions that are stored as computer-executable programs in the memory 125. For example, the processing circuitry 131 reads the computer programs from the memory 125 and executes them so as to implement the corresponding functions. In other words, upon reading the computer programs, the processing circuitry 131 becomes equipped with various functions.

In the explanation given above, a “processor” reads computer programs that correspond to the functions from the memory 125 and executes them. However, the embodiment is not limited to that case. For example, if the processor is a CPU, then it reads the computer programs stored in the memory 125 and executes them to implement the functions. On the other hand, if the processor is an ASIC; then, instead of storing computer programs in the memory 125, the concerned functions are directly embedded as logic circuits in the circuit of the processor. Meanwhile, a processor according to the present embodiment is not limited to be configured as an individual circuit. Alternatively, a plurality of independent circuits can be combined to constitute a single processor, and the functions can be implemented therein. Meanwhile, in the present example, a single memory circuit is used to store the computer programs corresponding to various processing functions. Alternatively, a plurality of memory circuits can be disposed in a dispersed manner, and the processing circuitry 131 can read computer programs from individual memory circuits.

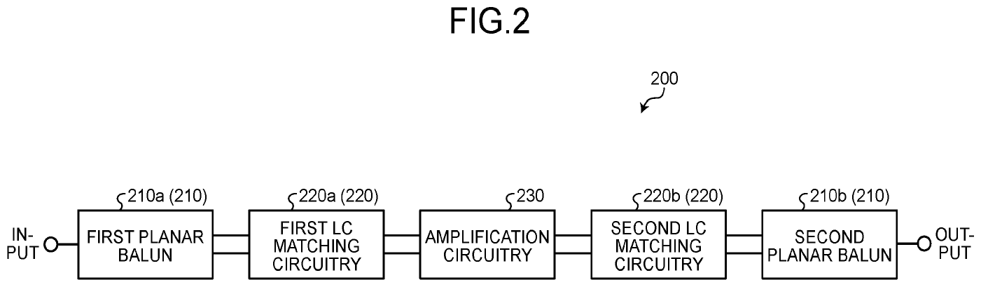

Given below is the explanation of the high-frequency amplification apparatus 200. FIG. 2 is a diagram illustrating an exemplary circuit configuration of the high-frequency amplification apparatus 200 according to the first embodiment. The high-frequency amplification apparatus 200 amplifies high-frequency signals. The high-frequency amplification apparatus 200 is installed in, for example, the transmission circuitry 113.

The high-frequency amplification apparatus 200 includes a first planar balun 210a (balun stands for balanced to unbalanced transformer), first LC (inductor-capacitor) matching circuitry 220a, amplification circuitry 230, second LC matching circuitry 220b, and a second planar balun 210b. When the first planar balun 210a and the second planar balun 210b need not be distinguished from each other, they are referred to as planar baluns 210. When the first LC matching circuitry 220a and the second LC matching circuitry 220b need not be distinguished from each other, they are referred to as LC matching circuitries 220.

The first planar balun 210a transforms unbalanced signals into balanced signals. Herein, the first planar balun 210a represents an example of a balun and a first-type balun. Meanwhile, unbalanced transmission is also called single-end transmission in which signals are transmitted using a single transmission channel. In balanced transmission, signals are transmitted using two transmission channels of differential signals. More specifically, to the first planar balun 210a, unbalanced signals are input according to unbalanced transmission from the input port of the high-frequency amplification apparatus 200. Then, the first planar balun 210a transforms the unbalanced signals into balanced signals. Moreover, the first planar balun 210a performs impedance conversion between the input side and the output side. Thus, the first planar balun 210a performs impedance conversion between the unbalanced-signal side and the balanced-signal side. Then, the first planar balun 210a outputs the balanced signals to the first LC matching circuitry 220a.

The first LC matching circuitry 220a is disposed between the first planar balun 210a and the amplification circuitry 230, and performs impedance matching. The first LC matching circuitry 220a represents an example of matching circuitry and first-type matching circuitry. That is, the first LC matching circuitry 220a performs impedance matching so as to achieve a suitable impedance for the amplification circuitry 230. For example, the first LC matching circuitry 220a performs impedance matching using a coil or a capacitor.

The amplification circuitry 230 amplifies the balanced signals output from the first LC matching circuitry 220a. For example, the amplification circuitry 230 is push-pull amplification circuitry. The amplification circuitry 230 is formed using, for example, a metal-oxide-semiconductor field-effect transistor (MOSFET).

The second LC matching circuitry 220b is disposed in between the amplification circuitry 230 and the second planar balun 210b, and performs impedance matching. The second LC matching circuitry 220b represents an example of second-type matching circuitry. That is, the second LC matching circuitry 220b performs impedance matching to achieve the impedance in accordance with the destination of the high-frequency amplification apparatus 200. The second LC matching circuitry 220b performs impedance matching using, for example, a coil or a reactance.

The second planar balun 210b transforms balanced signals based on balanced transmission into unbalanced signals based on unbalanced transmission. The second planar balun 210b represents an example of a second-type balun. More specifically, the second planar balun 210b transforms the balanced signals, which are output from the second LC matching circuitry 220b, into unbalanced signals. Moreover, the second planar balun 210b performs impedance conversion between the input side and the output side. Thus, the second planar balun 210b performs impedance conversion between the unbalanced signal side and the balanced signal side. Then, the second planar balun 210b outputs the unbalanced signals to the destination of the high-frequency amplification apparatus 200.

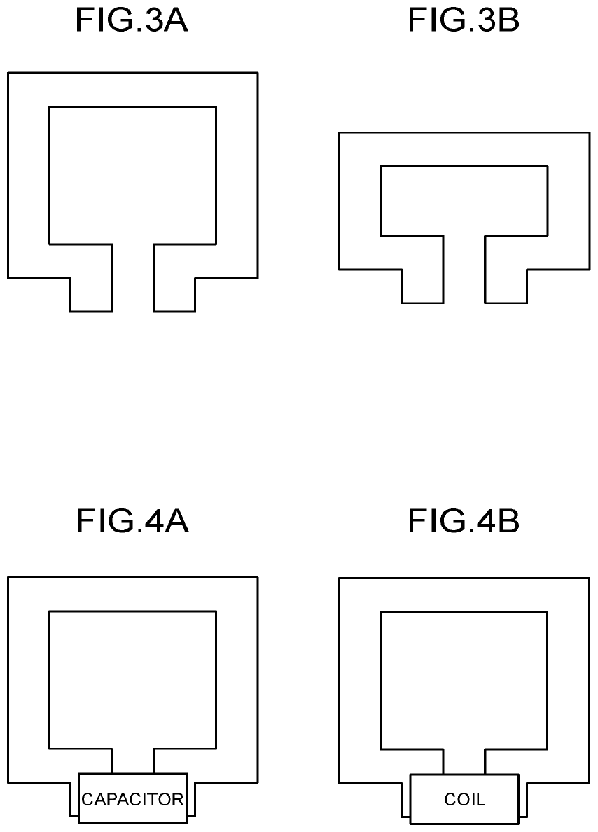

Generally, depending on the model thereof, each MRI apparatus has a different intensity of the magnetostatic field. For example, the intensity of the magnetostatic field can be equal to 1.5 tesla or 3.0 tesla. Conventionally, a planar balun is formed to have the size corresponding to the intensity of the magnetostatic field. FIG. 3 is a diagram illustrating examples of planar baluns corresponding to different intensities of the magnetostatic field. In (a) in FIG. 3 is illustrated an example of a planar balun corresponding to the intensity of 1.5 tesla. In (b) in FIG. 3 is illustrated an example of a planar balun corresponding to the intensity of 3.0 tesla.

A planar balun increases in size in inverse proportion to the frequency. That is, as illustrated in FIG. 3, the 1.5-tesla-compatible planar balun is formed to be greater than the 3.0-tesla-compatible planar balun. In the case of achieving a common configuration regardless of the intensity of the magnetostatic field, the planar balun needs to be compatible to 1.5 tesla. That is required to match with the wavelength and the coupling of the signals.

Moreover, in a planar balun, when the intensity of the magnetostatic field increases and the frequency increases, it results in an increase in the impedance. That is, there is a decrease in the impedance conversion rate in the planer balun. In the case of using a 1.5-tesla-compatible planar balun in a 3.0-tesla-compatible MRI apparatus, the LC matching circuitry is designed to have a constant impedance conversion rate in accordance with the impedance corresponding to the amplification circuitry. However, there is a limit to the impedance conversion rate of the LC matching circuitry.

In the case of using a 1.5-tesla-compatible planar balun in a 3.0-tesla-compatible MRI apparatus, since the impedance conversion rate of the planar balun has become lower, the LC matching circuitry becomes unable to perform impedance matching.

In that regard, it is possible to think of a method in which a coil or a capacitor is added to the planar balun. As a result of adding a coil or a capacitor, the impedance of the planar balun decreases. That is, as a result of adding a coil or a capacitor, it becomes possible to increase the impedance conversion rate in the planar balun. FIG. 4 is a diagram illustrating examples of planar baluns in which a coil and a capacitor are added. In (a) in FIG. 4 is illustrated an example of a planar balun in which a capacitor is added. In (b) in FIG. 4 is illustrated an example of a planar balun in which a coil is added. As illustrated in (a) or (b) in FIG. 4, as a result of adding a coil or a capacitor, the impedance of the planar balun decreases, thereby enabling achieving an increase in the impedance conversion rate. Hence, the LC matching circuitry becomes able to perform impedance matching.

However, if a coil or a capacitor is added to a planar balun, it results in an increase in the component count. Moreover, on the output side of the amplification circuitry, it becomes necessary to use high-withstand-voltage components. That leads to an increase in the component cost.

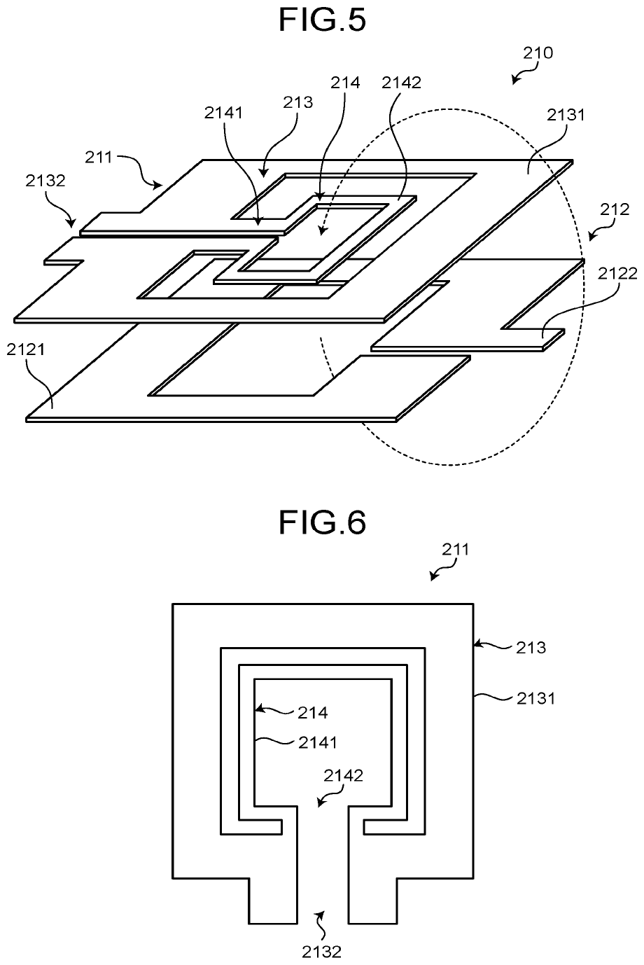

FIG. 5 is a perspective view illustrating an example of the planar balun 210 according to the present embodiment. FIG. 6 is a front view of an example of a first-layer balun 211 according to the present embodiment.

The planar balun 210 is formed on a laminar substrate having a plurality of layers. Moreover, the planar balun 210 is formed on a plurality of layers using printed wiring. As illustrated in FIG. 5, the planar balun 210 includes the first-layer balun 211 that is formed on the first layer of the substrate, and includes a second-layer balun 212 that is formed on the second layer of the substrate.

The first-layer balun 211 is connected to the amplification circuitry 230 via the LC matching circuitry 220. That is, the first-layer balun 211 of the first planar balun 210a is connected to the amplification circuitry 230 via the first LC matching circuitry 220a. Similarly, the first-layer balun 211 of the second planar balun 210b is connected to the amplification circuitry 230 via the second LC matching circuitry 220b.

The second-layer balun 212 is connected to the input port or the output port of the high-frequency amplification apparatus 200. That is, the second-layer balun 212 of the first planar balun 210a is connected to the input port of the high-frequency amplification apparatus 200; and the second-layer balun 212 of the second planar balun 210b is connected to the output port of the high-frequency amplification apparatus 200. Meanwhile, the planar balun 210 illustrated in FIG. 5 has a two-layered structure including the first-layer balun 211 and the second-layer balun 212. However, alternatively, the planar balun 210 can include three or more layers.

The first-layer balun 211 includes a main unit 213 and an auxiliary unit 214. The main unit 213 includes a main winding portion 2131 and a first connection portion 2132. The main winding portion 2131 is a coiled winding formed using printed wiring. The main winding portion 2131 illustrated in FIGS. 5 and 6 is formed in a rectangular shape because of the winding. However, the main winding portion 2131 is not limited to be formed in a rectangular shape, and can be formed in a circular shape or a polygonal shape. The first connection portion 2132 is formed at both ends of the main winding portion 2131 and is connected to the LC matching circuitry 220.

The auxiliary unit 214 is a winding formed using printed wiring. In other words, the auxiliary unit 214 represents an inductance. For that reason, the auxiliary unit 214 lowers the impedance of the planar balun 210. Thus, the auxiliary unit 214 enables achieving an increase in the impedance conversion rate of the planar balun 210. More specifically, the auxiliary unit 214 includes a joining portion 2141 and an auxiliary winding portion 2142. The auxiliary winding portion 2142 is a coiled winding formed using printed wiring. The joining portion 2141 is formed at both ends of the auxiliary winding portion 2142 and is connected to the first connection portion 2132 of the main unit 213. That is, the planar balun 210 includes the auxiliary winding portion 2142 that is connected to the ports of the planar balun 210. The auxiliary winding portion 2142 is connected in parallel to the main winding portion 2131.

Moreover, at least either in the first planar balun 210a or the second planar balun 210b, on the inside of the main winding portion 2131 that is in coil form, the auxiliary winding portion 2142 is formed in coil form using printed wiring. That is, from among a plurality of layers of the planar balun 210, the auxiliary winding portion 2142 is formed in coil form in the layer that is connected to the amplification circuitry 230. The auxiliary winding portion 2142 illustrated in FIG. 5 is formed in a rectangular shape. However, the auxiliary winding portion 2142 is not limited to be formed in a rectangular shape, and can be formed in a circular shape or a polygonal shape.

In the auxiliary winding portion 2142, the inductance gets decided according to the length and the width of the winding. Thus, depending on the required inductance, the length and the width of the winding are decided for the auxiliary winding portion 2142.

Meanwhile, with reference to FIGS. 5 and 6, the auxiliary winding portion 2142 is formed in a rectangular shape in an identical manner to the main winding portion 2131. Alternatively, the auxiliary winding portion 2142 can have a different shape than the main winding portion 2131. For example, the auxiliary winding portion 2142 can be circular in shape, and the main winding portion 2131 can be rectangular in shape.

The second-layer balun 212 includes a second layer winding portion 2121 and a second layer connection portion 2122. The second layer winding portion 2121 is formed using printed wiring. The second layer connection portion 2122 is provided at one end of the winding constituting the second layer winding portion 2121, and is formed using printed wiring. Moreover, the second layer connection portion 2122 is connected to the input port or the output port of the high-frequency amplification apparatus 200.

In this way, in the high-frequency amplification apparatus 200, the first planar balun 210a as well as the second planar balun 210b includes the auxiliary winding portion 2142.

With such a configuration, when an electrical current flows from the second layer winding portion 2121 to the second layer connection portion 2122, a magnetic field is generated in the first planar balun 210a in the direction of an arrow illustrated in FIG. 5. When a magnetic field is generated in the direction of the arrow illustrated in FIG. 5, an electrical current flows in the main winding portion 2131 due to electromagnetic induction. That is, in the main winding portion 2131, such an electrical current flows which has the phase shifted by 180° from the electrical current flowing in the second layer winding portion 2121. As a result, the first planar balun 210a transforms the input unbalanced signals of the unbalanced transmission into balanced signals of the balanced transmission.

Moreover, when an electrical current flows from the first connection portion 2132 to the main winding portion 2131, a magnetic field is generated in the direction of the arrow illustrated in FIG. 5. When a magnetic field is generated in the direction of the arrow illustrated in FIG. 5, an electrical current flows in the second layer winding portion 2121 due to electromagnetic induction. That is, in the second layer winding portion 2121, such an electrical current flows which has the phase shifted by 180° from the electrical current flowing in the main winding portion 2131. As a result, the second planar balun 210b transforms the input balanced signals of the balanced transmission into unbalanced signals of the unbalanced transmission.

Moreover, the auxiliary winding portion 2142, which is formed using printed wiring, functions as the inductance. Hence, the auxiliary winding portion 2142 appears to be an inductance placed in between both ends of the first connection portion 2132, thereby enabling achieving reduction in the impedance of the main winding portion 2131. Thus, the auxiliary unit 214 enables achieving an increase in the impedance conversion rate of the planar balun 210.

As explained above, the high-frequency amplification apparatus 200 according to the first embodiment includes the first planar balun 210a, the first LC matching circuitry 220a, the amplification circuitry 230, the second LC matching circuitry 220b, and the second planar balun 210b. At least either the first planar balun 210a or the second planar balun 210b includes the auxiliary winding portion 2142 having an auxiliary winding formed using printed wiring. The auxiliary winding portion 2142 appears to be an inductance, thereby enabling achieving reduction in the impedance of the planar balun 210 that includes the auxiliary winding portion 2142. Thus, without having to add a coil or a capacitor as illustrated in FIG. 4, the planar balun 210 enables achieving an increase in the impedance conversion rate. As a result, the LC matching circuitry 220 becomes able to perform impedance matching.

In this way, in the high-frequency amplification apparatus 200, even if a component such as a coil or a capacitor as illustrated in FIG. 4 is not added to the 1.5-tesla-compatible planar balun 210, the LC matching circuitry 220 becomes able to match with the amplification circuitry 230. That is, even if no component is added to the planar balun 210 having the size compatible to the intensity of 1.5 tesla, the high-frequency amplification apparatus 200 can still be used in the transmission circuitry 113 of the 3.0-tesla-compatible MRI apparatus 100. Thus, without having to add any component, the high-frequency amplification apparatus 200 enables achieving balun standardization.

Moreover, the planar balun 210 having the size compatible to the intensity of 1.5 tesla can be used in the transmission circuitry 113 of the MRI apparatus 100 compatible to the intensity of 3.0 tesla. Thus, without having to add a component such as a coil or a capacitor, the high-frequency amplification apparatus 200 can be used in the 1.5-tesla-compatible MRI apparatus 100 as well as in the 3.0-tesla-compatible MRI apparatus 100.

### First Modification Example

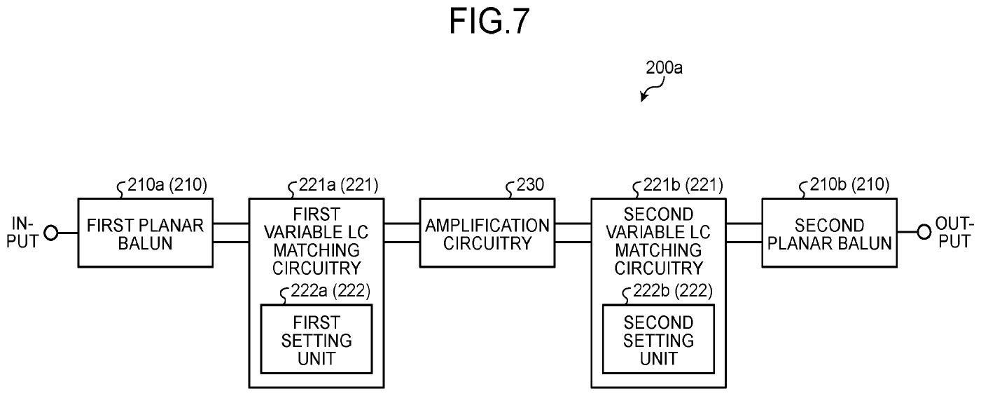

FIG. 7 is a diagram illustrating an exemplary circuit configuration of a high-frequency amplification apparatus 200a according to a first modification example. The high-frequency amplification apparatus 200a includes a first variable LC matching circuitry 221a in place of the first LC matching circuitry 220a, and includes a second variable LC matching circuitry 221b in place of the second LC matching circuitry 220b. The first variable LC matching circuitry 221a includes a first setting unit 222a; and the second variable LC matching circuitry 221b includes a second setting unit 222b. When the first variable LC matching circuitry 221a and the second variable LC matching circuitry 221b need not be distinguished from each other, they are referred to as variable LC matching circuitries 221. Moreover, when the first setting unit 222a and the second setting unit 222b need not be distinguished from each other, they are referred to as setting units 222.

The variable LC matching circuitry 221 includes an element capable of varying the impedance. For example, the variable LC matching circuitry 221 includes a variable capacitor whose capacitance can be varied, or includes a coil that enables varying the inductance by varying the coil radius and varying the cross-sectional area. Thus, using a variable capacitor or using a coil enabling varying the inductance, the variable LC matching circuitry 221 varies the impedance.

The setting unit 222 sets the impedance of the variable LC matching circuitry 221. More specifically, the setting unit 222 sets a constant number for the coil or the capacitor included in the variable LC matching circuitry 221. For example, the setting unit 222 varies the inductance by varying the radius of the coil included in the variable LC matching circuitry 221. Moreover, for example, the setting unit 222 varies the capacitance of the variable capacitor included in the variable LC matching circuitry 221. As a result, the setting unit 222 sets the impedance of the variable LC matching circuitry 221.

In this way, since the setting unit 222 sets the impedance of the variable LC matching circuitry 221, the intensity of the electromagnetic field can be made compatible to 1.5 tesla as well as to 3.0 tesla. That is, when the intensity of the electromagnetic field of the MRI apparatus 100 is variable, the setting unit 222 can make the variable LC matching circuitry 221 compatible to each intensity of the electromagnetic field.

The high-frequency amplification apparatus 200a illustrated in FIG. 7 includes the first variable LC matching circuitry 221a and the second variable LC matching circuitry 221b. However, either the first variable LC matching circuitry 221a can be replaced by the first LC matching circuitry 220a or the second variable LC matching circuitry 221b can be replaced by the second LC matching circuitry 220b. That is, the high-frequency amplification apparatus 200a either can include the first variable LC matching circuitry 221a including the first setting unit 222a, or can include the second variable LC matching circuitry 221b including the second setting unit 222b.

### Second Modification Example

The auxiliary winding portion 2142 illustrated in FIGS. 5 and 6 is formed on the inside of the main winding portion 2131. Alternatively, the auxiliary winding portion 2142 can be formed on the outside of the main winding portion 2131.

### Third Modification Example

The auxiliary winding portion 2142 illustrated in FIGS. 5 and 6 is formed in the first-layer balun 211. Alternatively, the auxiliary winding portion 2142 can be formed in the first-layer balun 211 as well as in the second-layer balun 212.

### Fourth Modification Example

In the high-frequency amplification apparatus 200 according to the first embodiment, the first planar balun 210a as well as the second planar balun 210b includes the auxiliary winding portion 2142. However, as long as the auxiliary winding portion 2142 is included in at least either the first planar balun 210a or the second planar balun 210b, it serves the purpose. That is, in the high-frequency amplification apparatus 200, the auxiliary winding portion 2142 that is connected to a port of the planar balun 210 can be included in at least either the first planar balun 210a or the second planar balun 210b.

Thus, according to at least one of the embodiments described above, standardization of the balun can be achieved without having to add any components.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A high-frequency amplifier apparatus that amplifies a high-frequency signal, comprising:
a balun that transforms an unbalanced signal, which is input, into a balanced signal;
amplification circuitry that amplifies the balanced signal output from the balun; and
matching circuitry that is disposed in between the balun and the amplification circuitry and that performs impedance matching, wherein
the balun includes an auxiliary winding that is connected to a port of the balun.

2. The high-frequency amplification apparatus according to claim 1, wherein
the balun represents a first-type balun,
the matching circuitry represents a first-type matching circuitry,
the high-frequency amplification apparatus further comprises
a second-type balun that transforms the balanced signal, which has been amplified by the amplification circuitry, into an unbalanced signal, and
second-type matching circuitry that is disposed in between the amplification circuitry and the second-type balun, and that performs impedance matching, and
the auxiliary winding is disposed in at least either the first-type balun or the second-type balun.

3. The high-frequency amplification apparatus according to claim 1, wherein
the balun is formed in coil form using printed wiring, and
the auxiliary winding is formed in coil form using printed wiring on inside of the balun in coil form.

4. The high-frequency amplification apparatus according to claim 1, wherein the balun is formed in a plurality of layers using printed wiring.

5. The high-frequency amplification apparatus according to claim 4, wherein the balun is formed in coil form in a layer connected to the amplification circuitry from among the plurality of layers.

6. The high-frequency amplification apparatus according to claim 1, wherein the matching circuitry includes a setting unit that sets impedance.

7. The high-frequency amplification device according to claim 1, wherein the auxiliary winding is formed in a circular shape or a polygonal shape.

8. A magnetic resonance imaging apparatus comprising a high-frequency amplification apparatus that amplifies a high-frequency signal, wherein
the high-frequency amplification apparatus includes
a balun that transforms an unbalanced signal, which is input, into a balanced signal,
amplification circuitry that amplifies the balanced signal output from the balun, and
matching circuitry that is disposed in between the balun and the amplification circuitry and that performs impedance matching, and
the balun includes an auxiliary winding that is connected to a port of the balun.
